(19) United States
(12) Patent Application Publication
(10) Pub. No.: US 2025/0226260 A1
(43) Pub. Date: Jul. 10, 2025

(54) METHOD FOR FORMING HYBRID SUBSTRATE OF SOI WAFER

(71) Applicant: Shanghai Huali Integrated Circuit Corporation, Shanghai (CN)

(72) Inventors: Zifang WANG, Shanghai (CN); Naoki TSUJI, Shanghai (CN); Tao WANG, Shanghai (CN)

(73) Assignee: Shanghai Huali Integrated Circuit Corporation, Shanghai (CN)

(21) Appl. No.: 18/810,415

(22) Filed: Aug. 20, 2024

(30) Foreign Application Priority Data
Jan. 4, 2024 (CN) 202410014314.0

(51) Int. Cl. H01L 21/762; H01L 21/02; H01L 21/311

(52) U.S. Cl. CPC H01L 21/76267; H01L 21/0214; H01L 21/02334; H01L 21/31138; H01L 21/31144; H01L 21/76283

(57) ABSTRACT

The application discloses a method for forming a hybrid substrate of a SOI wafer. Buried oxide and silicon-on-insulator in some areas are removed, a layer of SiOCN is deposited on a SOI sidewall to protect the silicon-on-insulator sidewall, and then the growth of epitaxial silicon is performed to cause the silicon substrate area to grow to be flush with the silicon-on-insulator area. The SiOCN on the SOI sidewall acts as a protective layer to prevent the growth of epitaxial silicon on the SOI sidewall, thereby preventing the generation of a bulge at a boundary between the SOI area and the silicon substrate area and improving the product yield. Moreover, a SiOCN film may be deposited with high conformality, and the SiOCN deposited on the SOI sidewall has good uniformity, so that the growth of epitaxial Si from the SOI does not occur during subsequent growth of the epitaxial silicon.

### CROSS-REFERENCE TO RELATED APPLICATIONS

This application claims priority to Chinese patent application No. 202410014314.0, filed on Jan. 4, 2024, the disclosure of which is incorporated herein by reference in its entirety.

### TECHNICAL FIELD

The present disclosure relates to semiconductor manufacturing technologies, and in particular, to a method for forming a hybrid substrate of a silicon-on-insulator (SOI) wafer.

### BACKGROUND

In a silicon-on-insulator (SOI) process, it is required to remove buried oxide silicon (BOX) and SOI in some areas, to form a silicon substrate area that acts as a well pickup area to apply a voltage to a well area and to form structures such as a diode.

When fully depleted SOI (FDSOI) is formed using a gate last process, the silicon substrate area is required to be flush with the SOI area, to ensure that subsequent chemical mechanical polishing (CMP) may be performed properly.

A process flow of an existing method for forming a hybrid substrate of a SOI wafer is as follows:
(1) depositing a layer of silicon oxide 4 and then depositing a layer of silicon nitride 5 on the SOI wafer;
(2) performing a lithography process to open an area where a silicon substrate is to be formed;
(3) removing the silicon nitride 5, the silicon oxide 4, silicon-on-insulator (SOI) 3, and buried oxide silicon (BOX) 2 in the silicon substrate area by dry etch;
(4) stripping a photoresist;
(5) removing, by wet cleaning, possible by-products generated by the dry etch, and then growing epitaxial silicon 9 to cause the silicon substrate area to grow to be flush with a SOI area;
(6) sequentially removing the silicon nitride 5 and the silicon oxide 4 by wet cleaning, and during a subsequent etch process for forming an active area, a boundary between the SOI area and the silicon substrate area would be etched to form a shallow trench isolation (STI).

However, since a SOI side face is exposed during the growth of the epitaxial silicon 9, silicon is also epitaxially grown on the SOI side face and then contacts silicon grown at the bottom, ultimately forming a high bulge 6 at the boundary between the SOI and the silicon substrate. Referring to FIG. 1, after the silicon nitride 5 and the silicon oxide 4 are removed, part of the silicon may be stripped. Moreover, during a subsequent etch process for forming an active area, the thickness of a bottom anti-reflection coating (BARC) may be caused to be non-uniform, and some areas may be excessively thick, resulting in block etch.

### BRIEF SUMMARY

The method for forming a hybrid substrate of a SOI wafer provided by the present disclosure includes the following steps:
S1: depositing a layer of mask silicon oxide 4 and then depositing a layer of mask silicon nitride 5 on the SOI wafer;
S2: performing a lithography process to open a silicon substrate area where a silicon substrate is to be formed;
S3: removing the mask silicon nitride 5, the mask silicon oxide 4, silicon-on-insulator (SOI) 3, and buried oxide silicon (BOX) 2 above the silicon substrate 1 in the silicon substrate area by dry etch;
S4: stripping a photoresist;
S6: depositing a layer of SiOCN 7;
S6: removing the SiOCN 7 on the SOI area and on the silicon substrate area by dry etch using the directionality of the dry etch, where side faces of the mask silicon oxide 4, the silicon-on-insulator (SOI) 3, and the buried oxide silicon (BOX) 2 are fully covered with the SiOCN, and a lower portion of the side face of the mask silicon nitride 5 is covered with the SiOCN;
S7: performing growth of epitaxial silicon 9 to cause an upper surface of substrate silicon 1 in the silicon substrate area to grow to be flush with an upper surface of the silicon-on-insulator (SOI) in the SOI area;
S8: removing the silicon nitride and the silicon oxide in the SOI area by wet cleaning;
S9: during a subsequent etch process for forming an active area, removing the SiOCN deposited at a boundary between the SOI area and the silicon substrate area by etch, to form a shallow trench isolation (STI).

In some example, after step S6, by-products generated in a dry etch process of step S6 are removed by wet cleaning, followed by step S7.

In some example, the by-products generated in the dry etch process of step S6 are removed by the wet cleaning using an acid cleaning agent of a first concentration;
the acid cleaning agent is phosphoric acid or hydrofluoric acid.

In some example, in step S8, the silicon nitride and the silicon oxide in the SOI area are removed by the wet cleaning using an acid cleaning agent of a second concentration, the second concentration being higher than the first concentration.

In some example, the thickness of the deposited SiOCN 7 in step S5 is 5-10 nm.

In some example, in step S1, the thickness of the mask silicon oxide 4 is 3-10 nm, and the thickness of the mask silicon nitride 5 is 10-30 nm.

In some example, in step S1, the thickness of the mask silicon oxide 4 is 50 Å; the thickness of the mask silicon nitride 5 is 150 Å;
the thickness of the deposited SiOCN 7 in step S5 is 80 Å.

In the method for forming a hybrid substrate of a SOI wafer of the present disclosure, buried oxide and insulator-on-silicon in some areas are removed, a layer of SiOCN is deposited on a SOI sidewall to protect the insulator-on-silicon sidewall, and then the growth of epitaxial silicon is performed to cause the silicon substrate area to grow to be flush with the insulator-on-silicon area. The SiOCN on the SOI sidewall acts as a protective layer to prevent the growth of epitaxial silicon on the SOI sidewall, thereby preventing the generation of a bulge at a boundary between the SOI area and the silicon substrate area and improving the product yield. Moreover, a silicon oxycarbonitride (SiOCN) film may be deposited with high conformality, and the SiOCN deposited on the SOI sidewall has good uniformity (better than the uniformity of silicon oxide formed on the SOI sidewall by RTO), so that the growth of epitaxial Si from the SOI does not occur during subsequent growth of the epitaxial silicon 9, which is conducive to further improvement of the product yield.

### BRIEF DESCRIPTION OF THE DRAWINGS

In order to more clearly explain the technical solutions of the present disclosure, the drawings required to be used in the present disclosure will be briefly described below. It is obvious that the drawings described below are merely some embodiments of the present disclosure, and those skilled in the art could also obtain other drawings on the basis of these drawings without the practice of inventive effort.

FIG. 1 is a schematic diagram of a structure formed after growth of epitaxial silicon in an existing method for forming a hybrid substrate of a SOI wafer;

FIG. 2 is a schematic diagram of a structure in which mask silicon oxide and mask silicon nitride are deposited on the SOI wafer;

FIG. 3 is a schematic diagram of a structure formed after the mask silicon nitride, the mask silicon oxide, SOI, and BOX in a silicon substrate area are removed by dry etch;

FIG. 4 is a schematic diagram of a structure formed after a layer of SiOCN is deposited in a method for forming a hybrid substrate of a SOI wafer according to an embodiment of the present disclosure;

FIG. 5 is a schematic diagram of a structure formed after SiOCN on a SOI area and on a silicon substrate area are removed by dry etch in the method for forming a hybrid substrate of a SOI wafer according to an embodiment of the present disclosure;

FIG. 6 is a schematic diagram of a structure in which epitaxial silicon in the silicon substrate area is grown to be flush with an upper surface of silicon in the SOI area in the method for forming a hybrid substrate of a SOI wafer according to an embodiment of the present disclosure;

FIG. 7 is a schematic diagram of a structure formed after the silicon nitride and the silicon oxide in the SOI area are removed by wet cleaning in the method for forming a hybrid substrate of a SOI wafer according to an embodiment of the present disclosure; and

FIG. 8 is a schematic diagram of a structure in which an active area is formed by an etch process and the SiOCN at a boundary between the SOI area and the silicon substrate area is removed by etch to form an STI in the method for forming a hybrid substrate of a SOI wafer according to an embodiment of the present disclosure.

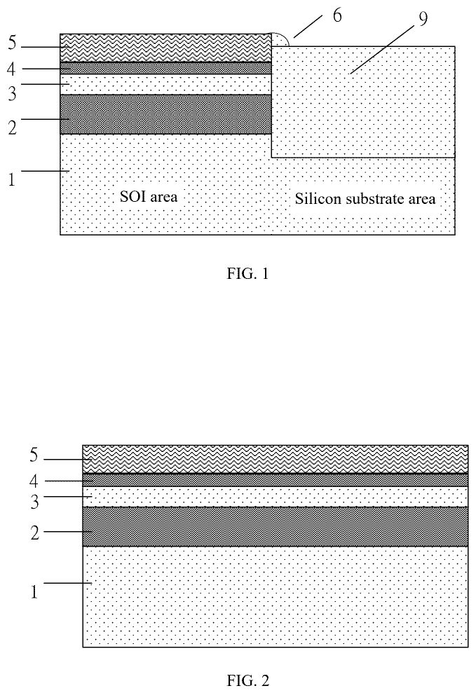

### LIST OF REFERENCE NUMERALS

1: substrate silicon, 2: buried oxide silicon (BOX), 3: silicon-on-insulator (SOI), 4: mask silicon oxide, 5: mask silicon nitride, 6: bulge formed by growth of epitaxial silicon, 7: SiOCN, and 9: epitaxial silicon.

### DETAILED DESCRIPTION OF THE DISCLOSURE

The technical solutions in the embodiments of the present disclosure will be clearly and completely described below in conjunction with the drawings. Obviously, the described embodiments are only part of the embodiments of the present disclosure, rather than all of the embodiments. Based on the embodiments in the present disclosure, all other embodiments obtained by those skilled in the art without the practice of inventive effort shall fall into the protection scope of the present disclosure.

The terms such as “first” and “second” used in the present application do not indicate any order, quantity, or importance, but are only used to distinguish different constituent parts. The terms such as “include” or “comprise” mean that the components or objects in front of these terms cover the components or objects listed after the terms and equivalents thereof, but does not exclude other components or objects. The terms such as “connection” or “coupling” are not limited to physical or mechanical connections, but may include electrical connections, whether direct or indirect. The terms such as “upper”, “lower”, “left”, “right”, “front”, and “rear” are only used to represent relative positional relationships, which may be changed accordingly after absolute positions of the described objects are changed.

It should be noted that the embodiments or features in the embodiments of the present disclosure can be combined with each other in the case of no conflicts.

### Embodiment I

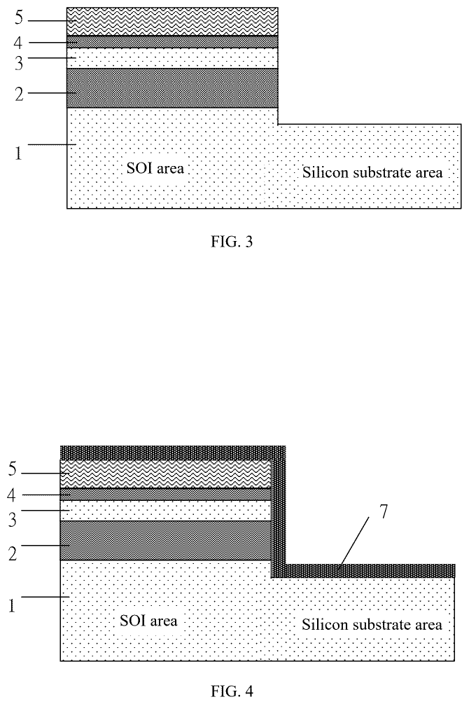

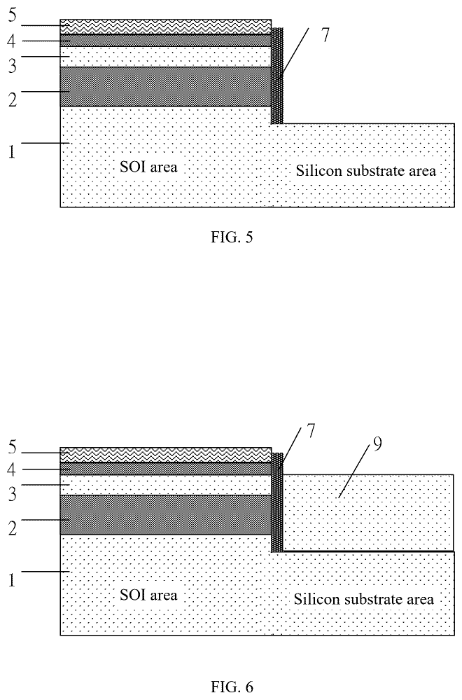

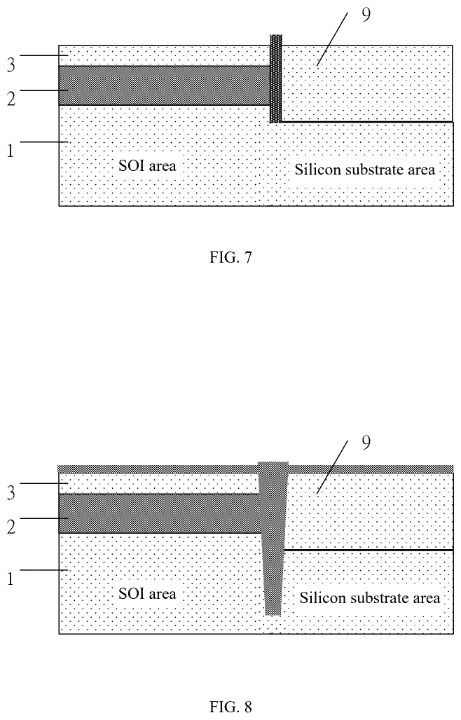

A method for forming a hybrid substrate of a silicon-on-insulator (SOI) wafer includes the following steps:
S1: depositing a layer of mask silicon oxide 4 and then depositing a layer of mask silicon nitride 5 on the SOI wafer, as shown in FIG. 2;
S2: performing a lithography process to open a silicon substrate area where a silicon substrate is to be formed;
S3: removing the mask silicon nitride 5, the mask silicon oxide 4, silicon-on-insulator (SOI) 3, and buried oxide silicon (BOX) 2 above the silicon substrate 1 in the silicon substrate area by dry etch;
S4: stripping a photoresist, as shown in FIG. 3;
S6: depositing a layer of SiOCN 7, as shown in FIG. 4;
S6: removing the SiOCN 7 on the SOI area and on the silicon substrate area by dry etch using the directionality of the dry etch, where side faces of the mask silicon oxide 4, the silicon-on-insulator (SOI) 3, and the buried oxide silicon (BOX) 2 are fully covered with the SiOCN, and a lower portion of the side face of the mask silicon nitride 5 is covered with the SiOCN, as shown in FIG. 5;
S7: performing growth of epitaxial silicon 9 to cause an upper surface of substrate silicon 1 in the silicon substrate area to grow to be flush with an upper surface of the silicon-on-insulator (SOI) in the SOI area, as shown in FIG. 6;
S8: removing the silicon nitride and the silicon oxide in the SOI area by wet cleaning, as shown in FIG. 7, where the SiOCN acts as a protective layer that is not easily consumed by processes such as wet cleaning, but the SiOCN at the top of the boundary between the SOI area and the silicon substrate area can be substantially removed during the wet cleaning;
S9: during a subsequent etch process for forming an active area, removing the SiOCN deposited at a boundary between the SOI area and the silicon substrate area by etch, to form a shallow trench isolation (STI), as shown in FIG. 8.

In the method for forming a hybrid substrate of a silicon-on-insulator (SOI) wafer of Embodiment I, buried oxide and insulator-on-silicon in some areas are removed, a layer of SiOCN is deposited on a SOI sidewall to protect the silicon-on-insulator sidewall, and then the growth of epitaxial silicon is performed to cause the silicon substrate area to grow to be flush with the silicon-on-insulator area. The SiOCN on the SOI sidewall acts as a protective layer to prevent the growth of epitaxial silicon on the SOI sidewall, thereby preventing the generation of a bulge at a boundary between the SOI area and the silicon substrate area and improving the product yield. Moreover, a silicon oxycarbonitride (SiOCN) film may be deposited with high conformality, and the SiOCN deposited on the SOI sidewall has good uniformity (better than the uniformity of silicon oxide formed on the SOI sidewall by RTO), so that the growth of epitaxial Si from the SOI does not occur during subsequent growth of the epitaxial silicon 9, which is conducive to further improvement of the product yield.

### Embodiment II

Based on the method for forming a hybrid substrate of a SOI wafer of Embodiment I, after step S6, by-products generated in a dry etch process of step S6 are removed by wet cleaning, followed by step S7.

In some example, the by-products generated in the dry etch process of step S6 are removed by the wet cleaning using an acid cleaning agent of a first concentration;
the acid cleaning agent is phosphoric acid or hydrofluoric acid.

In some example, in step S8, the silicon nitride and the silicon oxide in the SOI area are removed by the wet cleaning using an acid cleaning agent of a second concentration, the second concentration being higher than the first concentration.

### Embodiment III

Based on the method for forming a hybrid substrate of a SOI wafer of Embodiment I, the thickness of the deposited SiOCN 7 in step S5 is 5-10 nm.

In some example, in step S1, the thickness of the mask silicon oxide 4 is 3-10 nm, and the thickness of the mask silicon nitride 5 is 10-30 nm.

In some example, in step S1, the thickness of the mask silicon oxide 4 is 50 Å; the thickness of the mask silicon nitride 5 is 150 Å;
the thickness of the deposited SiOCN 7 in step S5 is 80 Å.

The above descriptions are merely examples of the embodiments of the present disclosure and are not intended to limit the present disclosure. Any modifications, equivalent substitutions, improvements, etc. made within the spirit and principles of the present disclosure shall be included within the protection scope of the present disclosure.

What is claimed is:

1. A method for forming a hybrid substrate of a SOI wafer, comprising the following steps:
S1: depositing a layer of mask silicon oxide and then depositing a layer of mask silicon nitride on the SOI wafer;
S2: performing a lithography process to open a silicon substrate area where a silicon substrate is to be formed;
S3: removing the mask silicon nitride, the mask silicon oxide, SOI, and BOX above the silicon substrate in the silicon substrate area by dry etch;
S4: stripping a photoresist;
S6: depositing a layer of SiOCN;
S6: removing the SiOCN on the SOI area and on the silicon substrate area by dry etch using the directionality of the dry etch, wherein side faces of the mask silicon oxide, the SOI, and the BOX are fully covered with the SiOCN, and a lower portion of the side face of the mask silicon nitride is covered with the SiOCN;
S7: performing growth of epitaxial silicon to cause an upper surface of substrate silicon in the silicon substrate area to grow to be flush with an upper surface of the SOI in the SOI area;
S8: removing the silicon nitride and the silicon oxide in the SOI area by wet cleaning;
S9: during a subsequent etch process for forming an active area, removing the SiOCN deposited at a boundary between the SOI area and the silicon substrate area by etch, to form an STI.

2. The method for forming a hybrid substrate of a SOI wafer according to claim 1, wherein after step S6, by-products generated in a dry etch process of step S6 are removed by wet cleaning, followed by step S7.

3. The method for forming a hybrid substrate of a SOI wafer according to claim 2, wherein
the by-products generated in the dry etch process of step S6 are removed by the wet cleaning using an acid cleaning agent of a first concentration;
the acid cleaning agent is phosphoric acid or hydrofluoric acid.

4. The method for forming a hybrid substrate of a SOI wafer according to claim 3, wherein in step S8, the silicon nitride and the silicon oxide in the SOI area are removed by the wet cleaning using an acid cleaning agent of a second concentration, the second concentration being higher than the first concentration.

5. The method for forming a hybrid substrate of a SOI wafer according to claim 1, wherein the thickness of the deposited SiOCN in step S5 is 5-10 nm.

6. The method for forming a hybrid substrate of a SOI wafer according to claim 5, wherein in step S1, the thickness of the mask silicon oxide is 3-10 nm, and the thickness of the mask silicon nitride is 10-30 nm.

7. The method for forming a hybrid substrate of a SOI wafer according to claim 6, wherein
in step S1, the thickness of the mask silicon oxide is 50 Å; the thickness of the mask silicon nitride is 150 Å;
the thickness of the deposited SiOCN in step S5 is 80 Å.
